(19) United States
(12) Patent Application Publication
(10) Pub. No.: US 2025/0089532 A1
(43) Pub. Date: Mar. 13, 2025

(54) DISPLAY PANEL AND DISPLAY DEVICE INCLUDING THE SAME

(71) Applicant: Samsung Display Co., LTD., Yongin-si (KR)

(72) Inventors: OHJUNE KWON, Yongin-si (KR); WOO YONG SUNG, Yongin-si (KR); SEUNGYONG SONG, Yongin-si (KR)

(21) Appl. No.: 18/748,900

(22) Filed: Jun. 20, 2024

(30) Foreign Application Priority Data
Sep. 11, 2023 (KR) 10-2023-0120522

(51) Int. Cl. H10K 59/80; H10K 71/40; H10K 77/10; H10K 102/00

(52) U.S. Cl. CPC H10K 59/873; H10K 71/421; H10K 77/111; H10K 2102/311

(57) ABSTRACT

A display panel, including a display area including a front area and a bending area, and a non-display area, includes a base layer, a light emitting element layer including a light emitting element and disposed on the base layer, and a thin film encapsulating layer disposed on the light emitting element layer. The thin film encapsulating layer includes a first encapsulating inorganic film disposed on the light emitting element layer, an encapsulating organic film disposed on the first encapsulating inorganic film, a second encapsulating inorganic film disposed on the encapsulating organic film, and a low-energy layer disposed on the first encapsulating inorganic film to correspond to the bending area and covered by the encapsulating organic film, and a surface energy of the low-energy layer is lower than a surface energy of the first encapsulating inorganic film.

This application claims priority to Korean Patent Application No. 10-2023-0120522, filed on Sep. 11, 2023, and all the benefits accruing therefrom under 35 U.S.C. § 119, the content of which in its entirety is herein incorporated by reference.

### BACKGROUND

### 1. Field

Embodiments of the disclosure described herein relate to a display panel and a display device including the display panel, and more particularly, relate to a display panel including a bending area, and a display device.

### 2. Description of the Related Art

A display device includes an active area that is activated based on an electric signal. The display device may sense a pressure that is applied from an outside through an active area, and may provide information to a user by displaying various images at the same time. In recent years, research for enlarging the active area in the display device has been made.

### SUMMARY

Embodiments of the disclosure provide a display panel, of which a durability of a bending area is enhanced, and a display device.

According to an embodiment, a display panel, including a front area, and a bending area bent from one side of the front area in one direction to have a curvature, includes a base layer, a light emitting element layer disposed on the base layer, where the light emitting element layer includes a light emitting element, and a thin film encapsulating layer disposed on the light emitting element layer, where the thin film encapsulating layer includes a first encapsulating inorganic film disposed on the first light emitting element layer, an encapsulating organic film disposed on the first encapsulating inorganic film, and a second encapsulating inorganic film disposed on the encapsulating organic film, where the second encapsulating inorganic film includes an upper surface spaced apart from the encapsulating organic film, and the upper surface of the second encapsulating inorganic film has a curved surface in a bent state, and a portion of the upper surface of the second encapsulating inorganic film corresponding to the bending area is convex in an opposite direction to the one direction in an unbent state.

In an embodiment, the second encapsulating inorganic film may include a lower surface contacting the encapsulating organic film, and the lower surface of the second encapsulating inorganic film may have a curved surface in the bent state, and a portion of the lower surface of the second encapsulating inorganic film corresponding to the bending area may be concave in the opposite direction in the unbent state.

In an embodiment, the encapsulating organic film may include an upper surface contacting the second encapsulating inorganic film, and the upper surface of the encapsulating organic film has a curved surface in the bent state, and a portion of the upper surface of the encapsulating organic film corresponding to the bending area may be convex in the opposite direction in the unbent state.

In an embodiment, the thin film encapsulating layer may further include a low-energy layer disposed on the first encapsulating inorganic film in correspondence to the bending area and covered by the encapsulating organic film, and a surface energy of the low-energy layer may be lower than a surface energy of the first encapsulating inorganic film.

In an embodiment, the low-energy layer may include an upper surface and a side surface, which contact the encapsulating organic film, and a whole portion of a front surface and a whole portion of the side surface of the low-energy layer may be covered by the encapsulating organic film.

In an embodiment, the display panel may further include a side area extending from one side of the bending area and spaced apart from the front area.

In an embodiment, the display panel may further include a side area extending from one side of the bending area and spaced apart from the front area, the first encapsulating inorganic film may include a first part corresponding to the front area, a second part corresponding to the bending area, and a third part corresponding to the side area, and surface energy of the first part and surface energy of the third part of the first encapsulating inorganic film may be higher than surface energy of the second part.

According to an embodiment, a display panel, including a display area including a front area, and a bending area bent from one side of the front area in one direction to have a curvature, and a non-display area adjacent to the display area, includes a base layer, a light emitting element layer disposed on the base layer, where the light emitting element layer includes a light emitting element, and a thin film encapsulating layer disposed on the light emitting element layer, where the thin film encapsulating layer includes a first encapsulating inorganic film disposed on the light emitting element layer, an encapsulating organic film disposed on the first encapsulating inorganic film, a second encapsulating inorganic film disposed on the encapsulating organic film, and a low-energy layer disposed on the first encapsulating inorganic film to correspond to the bending area, and covered by the encapsulating organic film, and a surface energy of the low-energy layer may be lower than a surface energy of the first encapsulating inorganic film.

In an embodiment, the second encapsulating inorganic film may include an upper surface spaced apart from the encapsulating organic film, and a lower surface contacting the encapsulating organic film, each of the upper surface and the lower surface of the second encapsulating inorganic film may include a curved surface in a bent state, a portion of the upper surface of the second encapsulating inorganic film corresponding to the bending area may be convex in an opposite direction to the one direction in an unbent state and a portion of the lower surface of the second encapsulating inorganic film corresponding to the bending area may be concave in the opposite direction in the unbent state.

In an embodiment, the first encapsulating inorganic film may include an upper surface contacting the encapsulating organic film, the encapsulating organic film may include an upper surface contacting the second encapsulating inorganic film, and a length of the bending area from the upper surface of the first encapsulating inorganic film to a most convex portion of the upper surface of the encapsulating organic film in the one direction may be 1.1 to 1.3 times of a length of the front area from the upper surface of the first encapsulating inorganic film to the upper surface of the encapsulating organic film in the one direction, in the unbent state.

In an embodiment, the display area further may include a side area extending from one side of the bending area and spaced apart from the front area, the first encapsulating inorganic film may include an upper surface contacting the encapsulating organic film, the encapsulating organic film may include an upper surface contacting the second encapsulating inorganic film, and, in the unbent state, a length of the bending area from the upper surface of the first encapsulating inorganic film to a most convex portion of the upper surface of the encapsulating organic film in the one direction may be 1.1 to 1.3 times of a length of the side area from the upper surface of the first encapsulating inorganic film to the upper surface of the encapsulating organic film in the one direction.

In an embodiment, the encapsulating organic film may include an upper surface contacting the second encapsulating inorganic film, and the upper surface of the encapsulating organic film may include a curved surface in a bent state and a portion of the upper surface of the encapsulating organic film corresponding to the bending area may be convex in an opposite direction to the one direction in an unbent state.

In an embodiment, the low-energy layer may include an upper surface and a side surface contacting the encapsulating organic film, and a whole portion of the upper surface and a whole portion of the side surface of the low-energy layer may be covered by the encapsulating organic film.

According to an embodiment, a display panel including a display area including a front area, a bending area bent from one side of the front area in one direction to have a curvature, and a side area extending from one side of the bending area and spaced apart from the front area, and a non-display area being adjacent to the display area includes a base layer, a light emitting element layer disposed on the base layer, where the light emitting element layer includes a light emitting element, and a thin film encapsulating layer disposed on the light emitting element layer, the thin film encapsulating layer includes a first encapsulating inorganic film disposed on the light emitting element layer, where the first encapsulating inorganic film includes a first part corresponding the front area, a second part corresponding to the bending area, and a third part corresponding to the side area, an encapsulating organic film disposed on the first encapsulating inorganic film, and a second encapsulating inorganic film disposed on the encapsulating organic film, and, in the first encapsulating inorganic film, a surface energy of the first part and a surface energy of the third part are higher than a surface energy of the second part.

In an embodiment, the first part and the third part of the first encapsulating inorganic film may be surface-treated with plasma.

In an embodiment, the second encapsulating inorganic film may include an upper surface spaced apart from the encapsulating organic film and a lower surface contacting the encapsulating organic film, and each of the upper surface and the lower surface of the second encapsulating inorganic film may include a curved surface corresponding to the bending area in a bent state, a portion of the upper surface of the second encapsulating inorganic film may be convex in an opposite direction to the one direction in correspondence to the bending area in an unbent state, and a portion of the lower surface of the second encapsulating inorganic film may be concave in the opposite direction in the unbent state.

In an embodiment, the first encapsulating inorganic film may include an upper surface contacting the encapsulating organic film, and, in the unbent state, a length of the bending area from the upper surface of the first encapsulating inorganic film to a most convex portion of the lower surface of the second encapsulating inorganic film in the one direction may be 1.1 to 1.3 times of a length of the front area from the upper surface of the first encapsulating inorganic film to the lower surface of the second encapsulating inorganic film in the one direction.

In an embodiment, the first encapsulating inorganic film may include an upper surface contacting the encapsulating organic film, and, in the unbent state, a length of the bending area from the upper surface of the first encapsulating inorganic film to a most convex portion of the lower surface of the second encapsulating inorganic film in the one direction may be 1.1 to 1.3 times of a length of the side area from the upper surface of the first encapsulating inorganic film to the lower surface of the second encapsulating inorganic film in the one direction.

In an embodiment, the encapsulating organic film may include an upper surface contacting the second encapsulating inorganic film, and the upper surface of the encapsulating organic film may include a curved surface in a bent state, and a portion of the upper surface of the encapsulating organic film corresponding to the bending area may be convex in an opposite direction in correspondence to the bending area in an unbent state.

In an embodiment, each of the first part, the second part, and the third part of the first encapsulating inorganic film may contact the encapsulating organic film.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of a coupled state of a display device according to an embodiment of the disclosure.

FIG. 2 is an exploded perspective view of a display device according to an embodiment of the disclosure.

FIG. 3 is a cross-sectional view of a display module according to an embodiment of the disclosure.

FIG. 4 is a plan view of a display panel according to an embodiment of the disclosure.

FIG. 5 is a cross-sectional view of a display panel according to an embodiment of the disclosure.

FIG. 6 is a cross-sectional view of a display panel according to an embodiment of the disclosure.

FIG. 7A is a cross-sectional view of a thin film encapsulating layer before bending according to an embodiment of the disclosure.

FIG. 7B is a cross-sectional view of a thin film encapsulating layer after bending according to an embodiment of the disclosure.

FIG. 8 is a cross-sectional view of a thin film encapsulating layer before bending according to an embodiment of the disclosure.

FIGS. 9A and 9B are schematic views illustrating contact angles depending on a height of surface energy according to an embodiment of the disclosure.

FIGS. 10A and 10D are enlarged plan views of a thin film encapsulating layer according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the specification, the expression that a first component (or area, layer, part, or the like) is “on”, “connected to”, or “coupled to” a second component means that the first component is directly on, connected to, or coupled to the second component or means that a third component is interposed therebetween.

In the application, the expression “directly disposed” may mean that neither of a layer, a film, an area, and a plate is present between a part, such as a layer, a film, and area, or a plate and another part. For example, the expression “directly disposed” may mean that a layer or a member is disposed between two layers or two members while an additional member, such as an adhesive member, is not used therebetween.

The same reference numerals refer to the same components. Further, in the drawings, the thickness, the ratio, and the dimension of components are exaggerated for effective description of technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Although the terms “first”, “second”, etc. may be used to describe various components, the components should not be limited by the terms. The terms are only used to distinguish one component from another component. For example, without departing from the right scope of the disclosure, a first component may be referred to as a second component, and similarly, the second component may be also referred to as the first component.

Also, the terms “under”, “below”, “on”, “above”, etc. are used to describe the correlation of components illustrated in drawings. The terms that are relative in concept are described based on a direction illustrated in drawings. In the specification, the expression “disposed on” may refer to a case, in which a member is disposed not only on another member but also under the another member.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical terms and scientific terms) used in the specification have the same meaning as commonly understood by those skilled in the art to which the disclosure belongs. Furthermore, terms such as terms defined in the dictionaries commonly used should be interpreted as having a meaning consistent with the meaning in the context of the related technology, and should not be interpreted in overly ideal or overly formal meanings unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

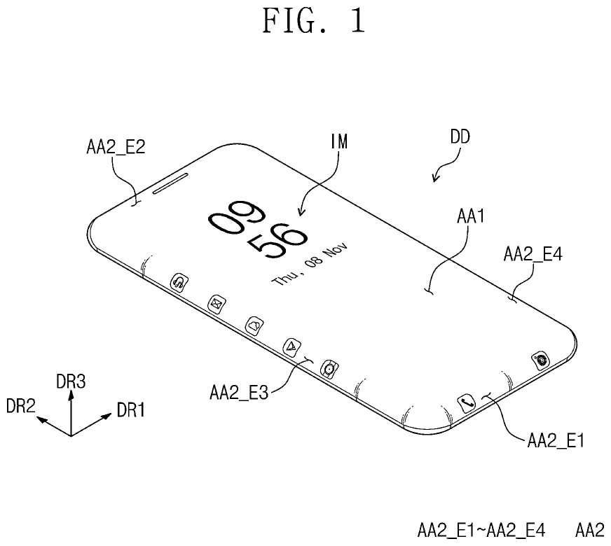

FIG. 1 is a perspective view of a coupled state of a display device DD according to an embodiment of the disclosure.

FIG. 1 illustrates an embodiment where the display device DD is a smartphone. However, the disclosure is not limited thereto, and the display device DD may be a middle/small-scale display device, such as a mobile phone, a tablet, a vehicle navigation system, a gaming device, or a smartwatch, including a large-scale display device, such as a television or a monitor.

Three-dimensional active areas AA1 and AA2, in which an image IM is displayed, may be defined in the display device DD. FIG. 1 illustrates images of a date, a time, and an icon, as examples of the image IM.

The three-dimensional active areas AA1 and AA2, in which the image IM is displayed, may include the first active area AA1 that has a flat surface shape, and the second active area AA2 that is bent from the first active area AA1. The first active area AA1 and the second active area AA2 are simply areas that are distinguished in shapes, and may implement (or collectively define) substantially one display surface (or integrally formed as a single unitary indivisible part).

The first active area AA1 may be parallel to a plane that is defined by a first direction DR1 and a second direction DR2. A normal direction of the first active area AA1 may be parallel to a third direction DR3. The third direction DR3 may be defined as a direction that is substantially perpendicular to the plane defined by the first direction DR1 and the second direction DR2, or a thickness direction.

Front surfaces (or upper surfaces) and rear surfaces (or lower surfaces) of members that constitute the display device DD may be opposed to each other in the third direction DR3, and normal directions of the front surfaces and the rear surfaces may be substantially parallel to the third direction DR3. Spacing distances between the front surfaces and the rear surfaces defined along the third direction DR3 may correspond to thicknesses of the members (or units).

In the specification, the expression “on a plane” may be defined as a state that is viewed in the third direction DR3. In the specification, the expression “on a cross-section” may be defined as a state that is viewed in the first direction DR1 or the second direction DR2. The directions that are indicated by the first to third directions DR1, DR2, and DR3 are relative concepts, and may be converted to different directions.

The second active area AA2 may be an area that is bent and extends from the first active area AA1. The second active area AA2 may be an area that is bent from the first active area AA1 while having a specific curvature. In an embodiment, a bezel area, in which the image IM is not displayed, may be defined around a portion of the second active area AA2.

The second active area AA2 may include a first edge active area AA2_E1, a second edge active area AA2_E2, a third edge active area AA2_E3, and a fourth edge active area AA2_E4, which are bent from sides of the first active area AA1. The second active area AA2 may include the first edge active area AA2_E1 that is bent from a first side of the first active area AA1, the second edge active area AA2_E2 that is bent from a second side of the first active area AA1, the third edge active area AA2_E3 that is bent from a third side of the first active area AA1, and the fourth edge active area AA2_E4 that is bent from a fourth side of the first active area AA1.

Although FIG. 1 illustrates an embodiment where the second active area AA2 includes the first to fourth edge active areas AA2_E1, AA2_E2, AA2_E3, and AA2_E4, the number of the edge active areas included in the second active area AA2 according to an embodiment of the disclosure may be changed if desired.

The first edge active area AA2_E1, the second edge active area AA2_E2, the third edge active area AA2_E3, and the fourth edge active area AA2_E4 may be bent to have specific curvatures with respect to a direction that is opposed to the third direction DR3, respectively. Each of the first edge active area AA2_E1, the second edge active area AA2_E2, the third edge active area AA2_E3, and the fourth edge active area AA2_E4 may have a single curvature.

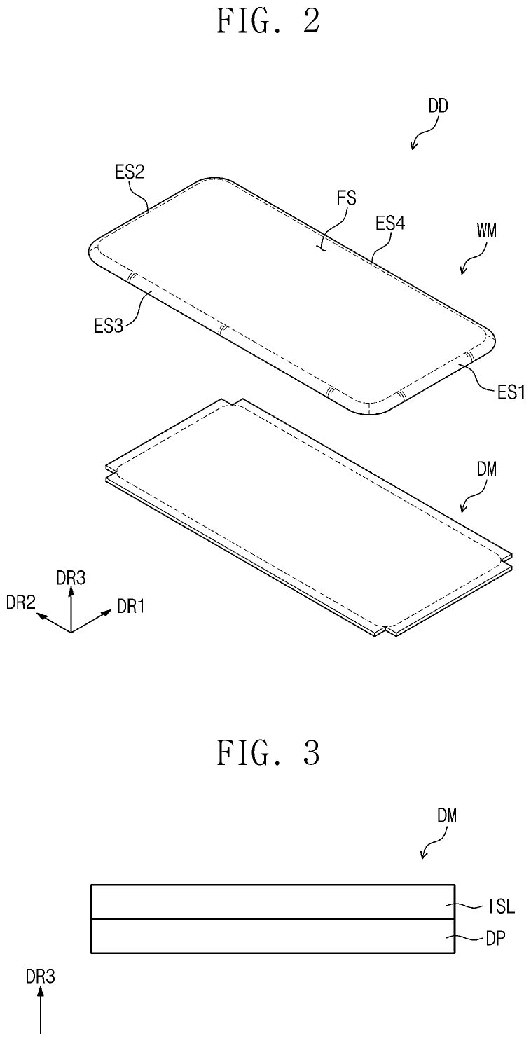

FIG. 2 is an exploded perspective view of the display device DD according to an embodiment of the disclosure.

FIG. 2 illustrates an embodiment where a display module DM is in an unbent state for convenience of illustration and description.

Referring to FIG. 2, an embodiment of the display device DD may include a window module WM, and the display module DM that is disposed under the window module WM.

The window module WM is disposed on the display module DM. The image IM (see FIG. 1) displayed on a display panel DP may be viewed to a user after passing through the window module WM. That is, a display surface of the display device DD may be defined in the window module WM.

The window module WM may include a base member and a bezel pattern. The base member may include a glass substrate or a plastic film, and may have a single-layer or multi-layer structure. The bezel pattern may be disposed on an outside area of the base member while overlapping the base member, and the bezel pattern may define the bezel area that has been described with reference to FIG. 1. However, if desired, the bezel pattern may be omitted in the window module WM according to an embodiment.

The window module WM may be optically transparent. The window module WM may include a glass board, and the glass board may be a tempered glass board that is chemically tempered. In an embodiment, the window module WM may have a single-layer structure including a glass board, but is not limited thereto. In another embodiment, the window module WM may have a multi-layer structure including a filler member or a polymer film that is disposed on the glass board.

The window module WM may include a front active area FS, side active areas ES1, ES2, ES3, and ES4 that are bent from the front active area FS. The front active area FS may correspond to the first active area AA1 (see FIG. 1) of the display device DD, and the side active areas ES1, ES2, ES3, and ES4 may correspond to the first to fourth edge active areas AA2_E1, AA2_E2, AS2_E3, and AA2_E4 (see FIG. 1). In the specification, the expression that an area and another area correspond to each other means that the areas overlap each other, and is not limited to a case having a same area as each other.

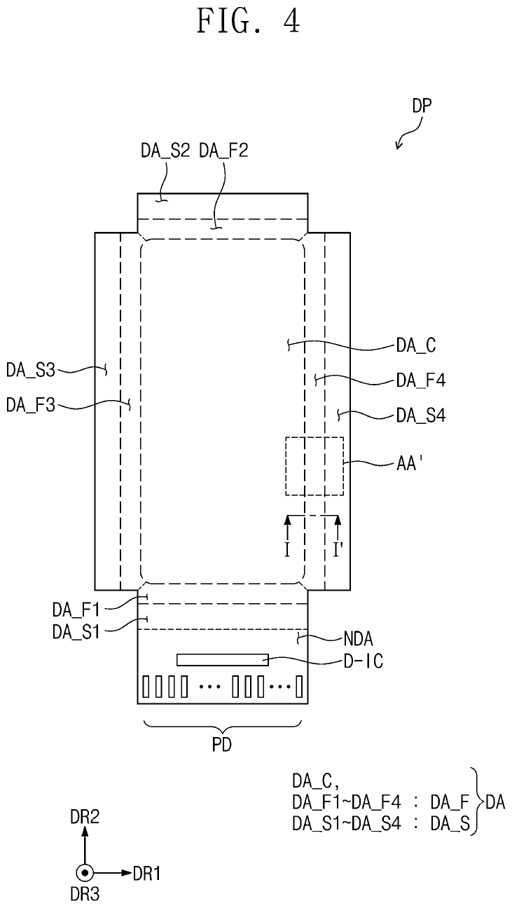

FIG. 3 is a cross-sectional view of the display module DM according to an embodiment of the disclosure.

Referring to FIG. 3, the display module DM according to an embodiment may include the display panel DP, and an input sensor ISL that is disposed on the display panel DP.

The display panel DP may generate the image IM (see FIG. 1). The display panel DP according to an embodiment may be a self-luminous display panel. In an embodiment, for example, the display panel DP may be a micro light emitting diode (LED) display panel, a nano LED display panel, an organic light emitting display panel, or a quantum dot light emitting display panel. However, this simply is an example, and is not limited as long as it is a self-luminous display panel.

A light emitting layer of the organic light emitting display panel may include an organic light emitting material. A light emitting layer of the quantum dot light emitting display panel may include quantum dots and/or quantum rods. The micro LED display panel may include a micro light emitting diode element that is an ultra-small light emitting element, and the nano LED display panel may include a nano light emitting diode element. Hereinafter, for convenience of description, embodiments where the display panel DP is an organic light emitting display panel will be described.

The input sensor ISL may be disposed on the display panel DP to acquire coordinate information of an external input. In an embodiment, for example, the external input may be an input by the user. The input by the user may include external input of various forms, such as a portion of the body of the user, light, heat, or a pressure. The input sensor ISL may be formed on the display panel DP through continuous processes. That is, the input sensor ISL may be directly disposed on the display panel DP. However, the embodiment is not limited thereto, and the input sensor ISL may be coupled onto the display panel DP through an adhesive member in another embodiment of the disclosure.

Although not illustrated, the display device DD may further include an optic layer (not illustrated) that is disposed between the display panel DP and the input sensor ISL or is disposed between the window module WM (see FIG. 2) and the display module DM. The optic layer (not illustrated) may include a reflection preventing member that decreases a reflection ratio of external light that is input from an outside.

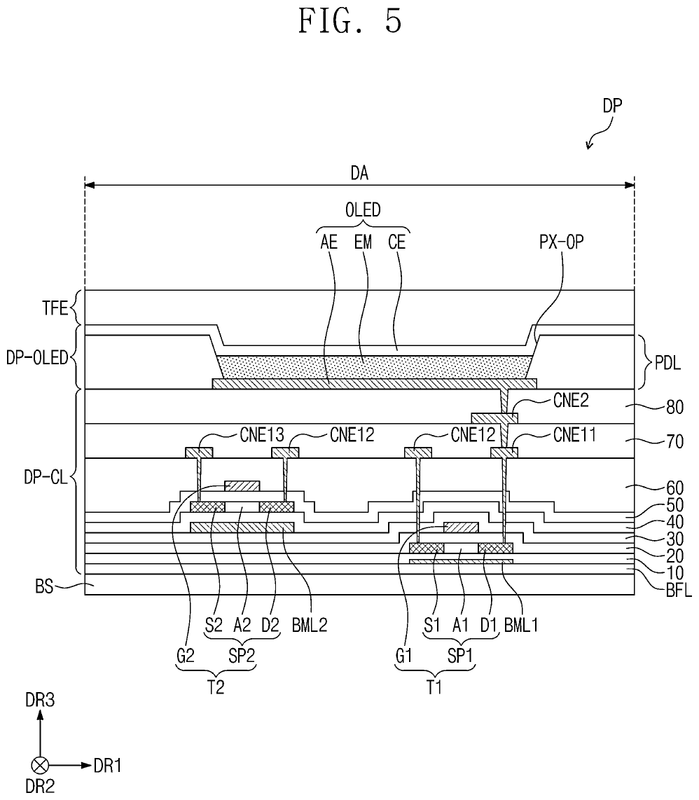

FIG. 4 is a plan view of the display panel DP according to an embodiment of the disclosure.

In FIG. 4, a structure of a display panel including a peripheral portion that is inserted into the display device DD (see FIG. 1) is omitted, and FIG. 4 illustrates only a bending area DA_F of the display device DD (see FIG. 1) in an unbent state, for convenience of illustration and description.

Referring to FIG. 4, an embodiment of the display panel DP may include a display area DA, in which the image IM (see FIG. 1), and a non-display area NDA that extends from a portion of the display area DA, and in which the image IM (see FIG. 1) is not displayed.

The display area DA may be a light emitting area, in which pixels are disposed. The display area DA may include a front area DA_C, the bending area DA_F, and a side area DA_S. The front area DA_C, the bending area DA_F, and the side area DA_S simply are areas that are distinguished in shapes, and may implement substantially as (or be defined by portions of) one display surface. The front area DA_C may be parallel to a plane that is defined by the first direction DR1 and the second direction DR2. The bending area DA_F may be an area that is bent from the front area DA_C to have a specific curvature and extends, and the side area DA_S may be an area that extends from the bending area DA_F and is spaced apart from the front area DA_C.

The front area DA_C may be an area that corresponds to the front active area FS (see FIG. 2) of the window module WM (see FIG. 2). Furthermore, the front area DA_C may correspond to a planar area that is smaller than the front active area FS (see FIG. 2) of the window module WM (see FIG. 2). That is, on a plane, an area of the front area DA_C may be smaller than an area of the front active area FS (see FIG. 2) of the window module WM (see FIG. 2).

The bending area DA_F may be defined as an area, of which a strain and/or a stress caused as it is bent to have a specific curvature is higher than the other areas of the display area DA. The bending area DA_F may include a first bending area DA_F1, a second bending area DA_F2, a third bending area DA_F3, and a fourth bending area DA_F4, which are bent from sides of the front area DA_C. The bending area DA_F may include the first bending area DA_F1 that is bent from a first side of the front area DA_C, the second bending area DA_F2 that is bent from a second side of the first active area AA1, the third bending area DA_F2 that is bent from a third side of the first active area AA1, and the fourth bending area DA_F4 that is bent from a fourth side of the first active area AA1. The first side and the second side may be substantially parallel to an imaginary line in the second direction DR2, and the third side and the fourth side may be substantially parallel to an imaginary line in the first direction DR1. The first side and the second side, and the third side and the fourth side may be perpendicular to each other on a plane, respectively.

In the specification, the expression of “substantially parallel” includes a case, in which differences between the distances of two reference lines are caused by an error range that is generated during a process in spite that they are designed as parallel lines, as well as a case, in which two lines do not meet each other regardless of how they extend.

The first bending area DA_F1 may be bent to have a first curvature, the second bending area DA_F2 may be bent to have a second curvature, the third bending area DA_F3 may be bent to have a third curvature, and the fourth bending area DA_F4 may be bent to have a fourth curvature. Curvatures of the first bending area DA_F1, the second bending area DA_F2, the third bending area DA_F3, and the fourth bending area DA_F4 may be substantially the same as each other, or some of the curvatures thereof may be different from each other while others of the curvatures thereof are the same as each other. In an embodiment, for example, the first curvature of the first bending area DA_F1 and the second curvature of the second bending area DA_F2 may be substantially the same as each other, and the third curvature of the third bending area DA_F3 and the fourth curvature of the fourth bending area DA_F4 may be substantially the same as each other, while being different from the first curvature of the first bending area DA_F1 and the second curvature of the second bending area DA_F2.

In the specification, the expression “the substantially the same” includes a case, in which a difference within an error range that may occur in a process is caused in spite of the same design, as well as a case, in which a refractive index or a thickness of a configuration is physically completely the same.

The first bending area DA_F1, the second bending area DA_F2, the third bending area DA_F3, and the fourth bending area DA_F4 may be areas corresponding to the first to fourth side areas ES1, ES2, ES3, and ES4 (see FIG. 2) of the window module WM (see FIG. 2). Furthermore, portions of the first bending area DA_F1, the second bending area DA_F2, the third bending area DA_F3, and the fourth bending area DA_F4 may correspond to the front active area FS (see FIG. 2) of the window module WM (see FIG. 2), and other portions of the first bending area DA_F1, the second bending area DA_F2, the third bending area DA_F3, and the fourth bending area DA_F4 may correspond to the first to fourth side areas ES1, ES2, ES3, and ES4 (see FIG. 2) of the window module WM (see FIG. 2), respectively.

Although FIG. 4 illustrates an embodiment where the bending area DA_F is in an unbent state with respect to the front area DA_C, the bending area of the display panel DP in the display device DD (see FIG. 1) provided to the user may be in a state where the bending area is bent in an opposite direction to the third direction DR3 (i.e., downwardly) to correspond to the first to fourth side areas ES1, ES2, ES3, and ES4 (see FIG. 2) of the window module WM (see FIG. 2).

The side area DA_S may include a first side area DA_S1, a second side area DA_S2, a third side area DA_S3, and a fourth side area DA_S4, which extend from the bending area DA_F. The side area DA_S may include the first side area DA_S1 that extends from the first bending area DA_F1, the second side area DA_S2 that extends from the second bending area DA_F2, the third side area DA_S3 that extends from the third bending area DA_F3, and the fourth side area DA_S4 that extends from the fourth bending area DA_F4.

The first side area DA_S1, the second side area DA_S2, the third side area DA_S3, and the fourth side area DA_S4 may be areas corresponding to the first to fourth side areas ES1, ES2, ES3, and ES4 (see FIG. 2) of the window module WM (see FIG. 2), respectively. The first side area DA_S1, the second side area DA_S2, the third side area DA_S3, and the fourth side area DA_S4 may have curvatures with respect to the front area DA_C, respectively. The side area DA_S has a curvature, but may be an area, of which a strain and/or a stress due to bending is lower than that of the bending area DA_F.

A driver integrated circuit (IC) (or a driving chip) D-IC and pads PD may be disposed in the non-display area NDA. The driver IC D-IC may be mounted on the display panel DP to provide a driving signal to the display area DA of the display panel DP. The non-display area NDA may be bent in a direction that faces a rear surface of the display panel DP and may be disposed under the rear surface of the display panel DP. However, the embodiment is not limited thereto, and the display device DD (see FIG. 1) according to another embodiment may further include a printed circuit board (not illustrated) that is connected to the display panel DP, and the driver IC D-IC may be mounted on the printed circuit board.

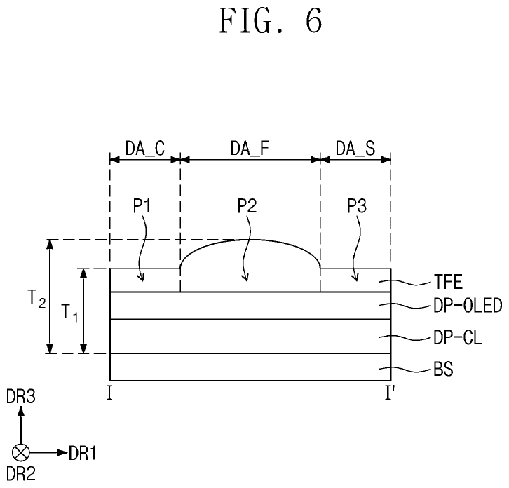

FIG. 5 is a cross-sectional view of the display panel DP according to an embodiment.

FIG. 5 is an enlarged cross-sectional view of a portion of the display panel DP to describe a circuit element layer DP-CL and a light emitting element layer DP-OLED in the display panel DP.

Referring to FIG. 5, the display panel DP according to an embodiment may include a base layer BS, the circuit element layer DP-CL that is disposed on the base layer BS, the light emitting element layer DP-OLED that is disposed on the circuit element layer DP-CL and includes a light emitting element OLED, and a thin film encapsulating layer TFE that is disposed on the light emitting element layer DP-OLED.

The base layer BS may be a member that provides a base surface, on which the circuit element layer DP-CL is disposed. The base layer BS may be a rigid substrate or a flexible substrate that may be bent, folded, or rolled. The base layer BS may be a substrate that includes a resin. In an embodiment, for example, the base layer BS may include a polyimide resin. However, the embodiment of the disclosure is not limited thereto, and the base layer BS may be an inorganic layer or a complex material layer.

The circuit element layer DP-CL may be disposed on the base layer BS. The circuit element layer DP-CL may include a buffer layer BFL, first to eighth insulating layers 10, 20, 30, 40, 50, 60, 70, and 80, light shielding patterns BML1 and BML2, transistors T1 and T2, connecting electrodes CNE11, CNE12, CNE13, and CNE2.

The buffer layer BFL may be disposed on the base layer BS. The buffer layer BFL may effectively prevent metal atoms or impurities from being diffused from the base layer BS to the transistors T1 and T2 on an upper side.

Each of the buffer layer BFL, and the first to eighth insulating layers 10, 20, 30, 40, 50, 60, 70, and 80 may include an inorganic layer and/or an organic layer, and may have a single-layer or multi-layer structure. The inorganic layer may include at least one of an aluminum oxide, a titanium oxide, a silicon oxide, a silicon nitride, a silicon oxynitride, a zirconium oxide, and a hafnium oxide. However, a material of the inorganic layer is not limited to the example. The organic layer may include at least any one of an acrylic resin, a methacrylic resin, a polyisoprene, a vinyl resin, an epoxy resin, a urethane resin, a cellulose resin, a siloxane resin, a polyamide resin, and a perylene resin. However, a material of the organic layer is not limited to the example.

The insulating layers included in the circuit element layer DP-CL are not limited to those illustrated in FIG. 5, and may be different according to a configuration of a pixel driving circuit included in the circuit element layer DP-CL and a process of forming the circuit element layer DP-CL.

The first light shielding pattern BML1 may be disposed on the buffer layer BFL. In an embodiment, the buffer layer BFL may be omitted, and the first light shielding pattern BML1 may be directly disposed on the base layer BS. The first light shielding pattern BML1 may include molybdenum. The first light shielding pattern BML1 may perform a shielding function. The first transistor T1 may be disposed on the first insulating layer 10, and may be covered by the second insulating layer 20 and the third insulating layer 30. The second light shielding pattern BML2 may be disposed on the third insulating layer 30. The second light shielding pattern BML2 may perform a shielding function. The second transistor T2 may be disposed on the fourth insulating layer 40, and may be covered by the fifth insulating layer 50 and the sixth insulating layer 60. Although FIG. 5 illustrates two transistors T1 and T2 of a pixel for convenience of illustration, the pixel in the circuit element layer DP-CL may include three or more transistors.

The first transistor T1 may include a first semiconductor pattern SP1 that is disposed on the first insulating layer 10. The first semiconductor pattern SP1 may include a first source S1, a first active A1, and a first drain D1. The first transistor T1 may include a first gate G1 that is disposed on the second insulating layer 20. Although not illustrated, an upper electrode may be further disposed on the first gate G1, and the first gate G1 and the upper electrode may form a storage capacitor.

The second transistor T2 may include a second semiconductor pattern SP2 that is disposed on the fourth insulating layer 40. The second semiconductor pattern SP2 may include a second source S2, a second active A2, and a second drain D2. The second transistor T2 may include a second gate G2 that is disposed on fifth insulating layer 50.

A first first connecting electrode CNE11 may be connected to the first drain D1 of the first transistor T1. The first first connecting electrode CNE11 may be connected to the first drain D1 through a contact hole defined through the second to sixth insulating layers 20 to 60. A second first connecting electrode CNE12 may be connected to the first source S1 of the first transistor T1. The second first connecting electrode CNE12 may be connected to the first source S1 through a contact hole defined through the second to sixth insulating layers 20 to 60. The second first connecting electrode CNE12 may extend on a plane, and may overlap the second drain D2 of the second transistor T2. The second first connecting electrode CNE12 may be connected to the second drain D2 through a contact hole defined through the fifth and sixth insulating layers 50 and 60. A third first connecting electrode CNE13 may be connected to the second source S2. The third first connecting electrode CNE13 may be connected to the second source S2 through a contact hole defined through the fifth and sixth insulating layers 50 and 60. The first to third first connecting electrodes CNE11 to CNE13 may be covered by the seventh insulating layer 70.

The second connecting electrode CNE2 may be connected to the first first connecting electrode CNE11 through a contact hole defined through the seventh insulating layer 70. The second connecting electrode CNE2 may be connected to the first drain D1 of the first transistor T1 through the first first connecting electrode CNE11. The second connecting electrode CNE2 may be covered by the eighth insulating layer 80. However, the embodiment is not limited thereto, and in another embodiment, the second connecting electrode CNE2 may be omitted or an additional connecting electrode disposed between the second connecting electrode CNE2 and the first first connecting electrode CNE11 may be further disposed in the circuit element layer DP-CL.

The light emitting element layer DP-OLED may be disposed on the circuit element layer DP-CL. The light emitting element layer DP-OLED may include the light emitting element OLED and a pixel definition film PDL.

The light emitting element OLED may include a first electrode EL1, a second electrode EL2 that faces the first electrode EL1, and a light emitting layer EM that is disposed between the first electrode EL1 and the second electrode EL2. Although FIG. 5 illustrates one light emitting element OLED as an example, and the disclosure is not limited thereto, and in an embodiment, the display panel DP may include two or more light emitting elements. In such an embodiment, the two or more light emitting elements may emit light of a same wavelength or emit light of different wavelengths.

The first electrode EL1 may be a transmissive electrode, a semi-transmissive electrode, or a reflective electrode. According to an embodiment of the disclosure, the first electrode EL1 may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, a mixture of two or more selected therefrom, or an oxide thereof. In an embodiment where the first electrode EL1 is a transmissive electrode, the first electrode EL1 may include a transparent metal oxide, for example, an indium tin oxide (ITO), an indium zinc oxide (IZO), a zinc oxide (ZnO), or an indium tin zinc oxide (ITZO). In an embodiment where the first electrode EL1 is a semi-transmissive electrode or a reflective electrode, the first electrode EL1 may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or mixture thereof (for example, a mixture of Ag and Mg). Alternatively, the first electrode EL1 may have a plurality of layer structures including a reflective film or semi-transmissive film including or formed of at least one selected from the above materials, and a transparent conductive film including or formed of an indium tin oxide (ITO), an indium zinc oxide (IZO), a zinc oxide (ZnO), or an indium tin zinc oxide (ITZO). In an embodiment, for example, the first electrode EL1 may have a three-layer structure of ITO/Ag/ITO, but the disclosure is not limited thereto.

The light emitting layer EM may be disposed on the first electrode EL1. On a plane, the light emitting layers EM of the light emitting elements OLED may be disposed to be spaced apart from each other to correspondence to light emitting openings PX-OP, and may be formed as a light emitting pattern. However, the disclosure is not limited thereto, and the light emitting layers EM of the light emitting elements OLED may be formed as an integral film to form a common layer. The light emitting layer EM may include an organic light emitting material and/or an inorganic light emitting material. In an embodiment, for example, the light emitting layer EM may include a fluorescent material, a phosphorescent material, a metal organic complex light emitting material, or quantum dots. The light emitting layer EM may emit color light of any one of red, green, and blue.

The second electrode EL2 may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected from these, a mixture of two or more selected therefrom, or oxides thereof. The second electrode EL2 may be a transmissive electrode, a semi-transmissive electrode, or a reflective electrode. In an embodiment where the second electrode EL2 is a transmissive electrode, the second electrode EL2 may include a transparent metal oxide, for example, an indium tin oxide (ITO), an indium zinc oxide (IZO), a zinc oxide (ZnO), or an indium tin zinc oxide (ITZO). In an embodiment where the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or mixture thereof (for example, a mixture of Ag and Mg). Alternatively, the second electrode EL2 may have a plurality of layer structures including a reflective film or semi-transmissive film including or formed of at least one selected from the above materials, and a transparent conductive film including or formed of an indium tin oxide (ITO), an indium zinc oxide (IZO), a zinc oxide (ZnO), or an indium tin zinc oxide (ITZO). In an embodiment, for example, the second electrode EL2 may include the above-described metal materials, a combination of two or more metal materials selected from the above-described metal materials, or oxides of the above-described metal materials.

The pixel definition film PDL may be disposed on the insulating layer 80, and may cover a portion of the first electrode EL1 of the light emitting element OLED. That is, the pixel definition film PDL may expose a portion of the first electrode EL1. The light emitting openings PX-OP that expose corresponding portions of the first electrode EL1 while overlapping the first electrode EL1 may be defined in the pixel definition film PDL. The pixel definition film PDL may include a polymer resin. In an embodiment, for example, the pixel definition film PDL may include a polyacrylate resin or a polyimide resin. The disclosure is not limited thereto, and the pixel definition film PDL may further include an inorganic material. The pixel definition film PDL may further include a light absorbing material. In an embodiment, for example, the pixel definition film PDL may include a black coloring agent such as a black dye or a black pigment. In an embodiment, for example, the black coloring agent may include carbon black, a metal such as chrome, or an oxide thereof. However, the embodiment is not limited thereto.

The thin film encapsulating layer TFE may be disposed on the light emitting element layer DP-OLED. The thin film encapsulating layer TFE may seal the light emitting elements OLED by covering the light emitting element layer DP-OLED. The thin film encapsulating layer TFE may include at least one thin film of an inorganic film and an organic film. In an embodiment, the thin film encapsulating layer TFE may include inorganic films, and an organic film that is disposed between the inorganic films. The inorganic films of the thin film encapsulating layer TFE may protect the light emitting elements OLED from moisture and/or oxygen. The organic film of the thin film encapsulating layer TFE may protect the light emitting elements OLED from foreign substances, such as dust particles. The thin film encapsulating layer TFE will be described below in detail.

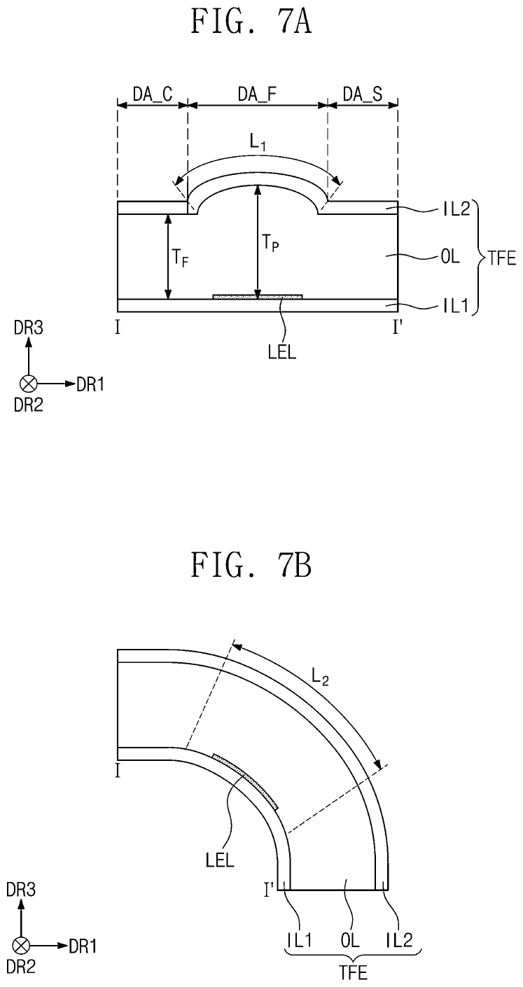

FIG. 6 is a cross-sectional view of the display panel DP (see FIG. 4) according to an embodiment of the disclosure.

FIG. 6 is a cross-sectional view taken along line I-I′ of FIG. 4, and illustrates the fourth bending area DA_F4 (see FIG. 4) and the fourth side area DA_S4 (see FIG. 4) as an example. The features of the fourth bending area DA_F4 (see FIG. 4) and the fourth side area DA_S4 (see FIG. 4) may be to the same as those of the first to third bending areas DA_F1, DA_F2, and DA_F3 (see FIG. 4) and the first to third side areas DA_S1, DA_S2, and DA_S3 (see FIG. 4), and any repetitive detailed description thereof will be omitted for convenience of description.

In FIG. 6 and the following drawings, the fourth bending area DA_F4 (see FIG. 4) and the fourth side area DA_S4 (see FIG. 4) will be illustrated and denoted as the bending area DA_F and the side area DA_S as an example of the first to fourth bending areas DA_F1, DA_F2, DA_F3, and DA_F4 (see FIG. 4) and the first to fourth side areas DA_S1, DA_S2, DA_S3, and DA_S4 (see FIG. 4).

Referring to FIG. 6, the thin film encapsulating layer TFE may include a first encapsulation part P1 corresponding to the front area DA_C, a second encapsulation part P2 corresponding to the bending area DA_F, and a third encapsulation part P3 corresponding to the side area DA_S.

The second encapsulation part P2, as illustrated in FIG. 6, may protrude in the third direction DR3 as compared with the adjacent first and third encapsulation parts P1 and P3 in the unbent state. That is, an upper surface of the second encapsulation part P2 may have a curvature. In an embodiment, for example, the upper surface of the second encapsulation part P2 may have substantially a same curvature as a curvature of the bending area DA_F in the bent state.

A first distance T1 from the upper surface of the base layer BS to the upper surface of the first encapsulation part P1 may be smaller than a second distance T2 from the upper surface of the base layer BS to the upper surface of the second encapsulation part P2. The second distance T2 may be defined as a distance from the upper surface of the base layer BS to a portion of the upper surface of the second encapsulation part P2, which protrudes most, (or an uppermost point of the upper surface). A third distance from the upper surface of the base layer BS to the upper surface of the third encapsulation part P3 may be smaller than the second distance T2.

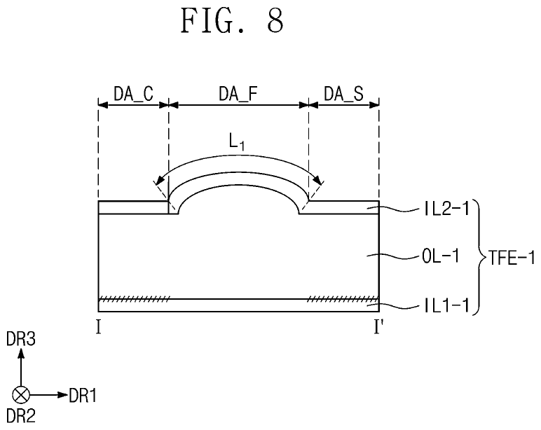

FIG. 7A is a cross-sectional view of the thin film encapsulating layer TFE before bending according to an embodiment of the disclosure. FIG. 7B is a cross-sectional view of the thin film encapsulating layer TFE after bending according to an embodiment of the disclosure.

FIGS. 7A and 7B are cross-sectional views taken along line I-I′ of FIG. 4, respectively, and illustrate the fourth bending area DA_F4 (see FIG. 4) and the fourth side area DA_S4 (see FIG. 4). As described in FIG. 6, in FIGS. 7A and 7B, the fourth bending area DA_F4 (see FIG. 4) and the fourth side area DA_S4 (see FIG. 4) are illustrated and denoted as the bending area DA_F and the side area DA_S.

Referring to FIGS. 7A and 7B, the thin film encapsulating layer TFE may include a first encapsulating inorganic film IL1 that is disposed on the light emitting element layer DP-OLED (see FIG. 6), an encapsulating organic film OL that is disposed on the first encapsulating inorganic film IL1, and a second encapsulating inorganic film IL2 that is disposed on the encapsulating organic film OL.

The first encapsulating inorganic film IL1 and the second encapsulating inorganic film IL2 may protect the light emitting elements OLED (see FIG. 5) from moisture and/or oxygen. Each of the first encapsulating inorganic film IL1 and the second encapsulating inorganic film IL2 may include at least one selected from an aluminum oxide, a titanium oxide, a silicon oxide, a silicon nitride, a silicon oxynitride, a zirconium oxide, and a hafnium oxide. However, the materials of the first encapsulating inorganic film IL1 and the second encapsulating inorganic film IL2 are not limited thereto.

The encapsulating organic film OL disposed between the first encapsulating inorganic film IL1 and the second encapsulating inorganic film IL2 may protect the light emitting elements OLED (see FIG. 5) from foreign substances, such as dust particles. The encapsulating organic film OL may include a monomer and a polymer. In an embodiment, for example, the encapsulating organic film OL may include an acryl resin. However, the material of the encapsulating organic film OL is not limited to the example.

Referring to FIG. 7A, the thin film encapsulating layer TFE according to an embodiment may further include a low-energy layer LEL. The surface energy of the low-energy layer LEL may be lower than the surface energy of the first encapsulating inorganic film IL1.

The lower-energy layer LEL may include an inorganic material or an organic material. In an embodiment, for example, where the low-energy layer LEL includes an inorganic material, the low-energy layer LEL may include a silicon nitride (SiNx). In an embodiment, for example, where the low-energy layer LEL includes an organic material, the low-energy layer LEL may include Teflon. The material of the low-energy layer LEL is not limited thereto, and may be coated transparently, and any material may be used as long as it has surface energy that is lower than the surface energy of the first encapsulating inorganic film IL1.

The low-energy layer LEL may be disposed on the first encapsulating inorganic film IL1. The low-energy layer LEL may be covered by the encapsulating organic film OL. In detail, the low-energy layer LEL may include an upper surface and a side surface that contact the encapsulating organic film OL, and the whole surface of the upper surface and the whole surface of the side surface of the encapsulating organic film OL may be covered by the encapsulating organic film OL.

The low-energy layer LEL may be disposed to correspond to the bending area DA_F. The low-energy layer LEL may be disposed to overlap a portion or an entirety of the bending area DA_F. When a length in the first direction DR1 is defined as a width, as illustrated in FIG. 7A, the width of the low-energy layer LEL may be smaller than the width of the bending area DA_F.

In an embodiment, the width of the low-energy layer LEL may be the same as or greater than the width of the bending area DA_F. In an embodiment where the width of the low-energy layer LEL is greater than the width of the bending area DA_F, a portion of the low-energy layer LEL may overlap a portion of the front area DA_C and a portion of the side area DA_S.

When the display panel DP (see FIG. 4) is in the unbent state, the upper surface of the encapsulating organic film OL may include a curved surface that is convex in the third direction DR3 (or upwardly). Here, the upper surface of the encapsulating organic film OL may mean a surface that contacts the second encapsulating inorganic film IL2.

In detail, when the display panel DP (see FIG. 4) is in the unbent state, a portion of the encapsulating organic film OL disposed on the low-energy layer LEL may protrude as compared with another portion of the encapsulating organic film OL disposed on the first encapsulating inorganic film IL1. When the display panel DP (see FIG. 4) is in the unbent state, the upper surface of a portion of the encapsulating organic film OL, which is disposed on the low-energy layer LEL, may be a curved surface that is convex in the third direction DR3.

Because the upper surface of the encapsulating organic film OL corresponding to the bending area DA_F when the display panel DP (see FIG. 4) is in the unbent state, each of the upper surface and the lower surface of the second encapsulating inorganic film IL2 formed on the encapsulating organic film OL may include a curved surface that is convex or concave. That is, a portion of the upper surface of the second encapsulating inorganic film IL2, which corresponds to the bending area DA_F may be a convex curved surface, and a portion of the lower surface thereof, which corresponds to the bending area DA_F, may be a concave curved surface.

When a length from the upper surface of the first encapsulating inorganic film IL1 to the lower surface of the second encapsulating inorganic film IL2 in the third direction DR3 is defined as a thickness of the encapsulating organic film OL, the thickness of the encapsulating organic film OL in the bending area DA_F in the unbent state may be greater than the thickness of the encapsulating organic film OL in the front area DA_C. Furthermore, in the unbent state, the thickness of the encapsulating organic film OL in the bending area DA_F may be greater than the thickness of the encapsulating organic film OL in the side area DA_S. The thickness of the encapsulating organic film OL in the front area DA_C may be substantially the same as the encapsulating organic film OL in the side area DA_S.

In the unbent state, a length T_{P} from the upper surface of the first encapsulating inorganic film IL1 to a most convex portion of the upper surface of the encapsulating organic film OL in the third direction DR3 in the bending area DA_F may be 1.1 to 1.3 times of a length T_{F} from the upper surface of the first encapsulating inorganic film IL1 to the upper surface of the encapsulating organic film OL in the third direction DR3 in the front area DA_C.

Because a portion of the upper surface of the second encapsulating inorganic film IL2, which corresponds to the bending area DA_F, and a portion of the lower surface thereof, which corresponds to the bending area DA_F, are curved surfaces, respectively, in the unbent state (before bending), a durability of the bending area DA_F may be enhanced as compared with a case, in which the upper surface and the lower surface of the second encapsulating inorganic film include no curved surface in the unbent state (before bending).

A tensile strain (¿) due to bending of the bending area DA_F may be calculated schematically based on the following equation. In the following equation, “L” denotes a length before bending and “ΔL” denotes a changed length after bending.

s=ΔL/L

Referring to FIGS. 7A and 7B, L₁ may corresponds to “L” and L₂−L₁ may correspond to “ΔL”. As compared with a case, in which the upper surface of the second encapsulating inorganic film includes no curved surface in the unbent state, after bending, “L” is relatively large and “ΔL” is relatively small in a case, in which the upper surface of the second encapsulating inorganic film IL2 includes a curved surface as in an embodiment of the disclosure.

That is, when it is assumed that the length L₂ of the bending area DA_F after bending is the same in case in which the upper surface of the second encapsulating inorganic film includes no curved surface in the unbent state and in the case in which the upper surface of the second encapsulating inorganic film IL2 includes a curved surface, the strain (ε) due to the bending may become smaller in the case in which the upper surface of the second encapsulating inorganic film IL2 includes a curved surface and thus, the stress applied to the bending area DA_F may become lower when the length L₁ is larger as the bending area DA_F before bending includes a curved surface as in an embodiment of the disclosure.

Because the stress applied to the bending area DA_F decreases, a durability of the bending area DA_F against a crack due to the bending may be enhanced.

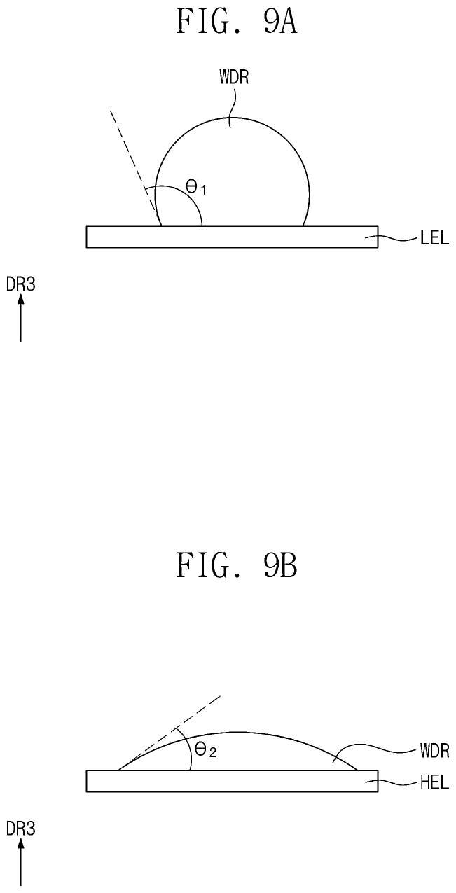

FIG. 8 is a cross-sectional view of a thin film encapsulating layer TFE-1 before bending according to an embodiment of the disclosure.

FIG. 8 is a cross-sectional view taken along line I-I′ of FIG. 4, and illustrates another embodiment of the fourth bending area DA_F4 (see FIG. 4) and the fourth side area DA_S4 (see FIG. 4). As described in FIG. 6, in FIG. 8, the fourth bending area DA_F4 (see FIG. 4) and the fourth side area DA_S4 (see FIG. 4) are illustrated and denoted as the bending area DA_F and the side area DA_S.

The embodiment of FIG. 8 is substantially the same as the embodiment of FIG. 7A, except that the low-energy layer LEL (see FIG. 7A) is not included and a partial area of a first encapsulating inorganic film IL1-1 is surface-treated.

In the first encapsulating inorganic film IL1-1, surface energy of the first part P1 (see FIG. 6) and surface energy of the third part P3 (see FIG. 6) may be higher than surface energy of the second part P2 (see FIG. 6). The first to third parts P1, P2, and P3 (see FIG. 6) may correspond to the front area DA_C, the bending area DA_F, and the side area DA_S, respectively.

The front area DA_C and the side area DA_S of the first encapsulating inorganic film IL1-1 may be surface-treated with plasma, and may have higher surface energy than the bending area DA_F of the first encapsulating inorganic film IL1-1.

When the display panel DP (see FIG. 4) is in the unbent state, the upper surface of a first encapsulating organic film OL-1 may include a curved surface that is convex in the third direction DR3. Here, the upper surface of the first encapsulating organic film OL-1 may mean a surface that contacts the second encapsulating inorganic film IL2-1.

In detail, when the display panel DP (see FIG. 4) is in the unbent state, a portion of the encapsulating organic film OL-1 disposed on the first encapsulating inorganic film IL1-1, which is not surface-treated with plasma, may protrude as compared with another portion of the encapsulating organic film OL-1 disposed on the area of the first encapsulating inorganic film IL1-1, which is surface-treated with plasma. When the display panel DP (see FIG. 4) is in the unbent state, an upper surface of a portion of the encapsulating organic film OL-1 on an area of the first encapsulating inorganic film IL1-1, which is not surface-treated, may be a curved surface that convex in the third direction DR3.

Because an upper surface of the encapsulating organic film OL-1, which corresponds to the bending area DA_F, includes a convex curved surface when the display panel DP (see FIG. 4) is in the unbent state, both of the upper surface and the lower surface of the second encapsulating inorganic film IL2-1 formed on the encapsulating organic film OL-1 may include curved surfaces. That is, a portion of the upper surface of the second encapsulating inorganic film IL2, which corresponds to the bending area DA_F may be a convex curved surface, and a portion of the lower surface thereof, which corresponds to the bending area DA_F, may be a concave curved surface.

A length from the upper surface of the first encapsulating inorganic film IL1-1 to the lower surface of the second encapsulating inorganic film IL2-1 in the third direction DR3 is defined as a thickness of the encapsulating organic film OL-1, in the unbent state, a thickness of the encapsulating organic film OL-1 in the bending area DA_F may be greater than a thickness of the encapsulating organic film OL-1 in the front area DA_C. Furthermore, the thickness of the encapsulating organic film OL-1 in the bending area DA_F may be greater than the thickness of the encapsulating organic film OL-1 in the side area DA_S. The thickness of the encapsulating organic film OL-1 in the front area DA_C and the thickness of the encapsulating organic film OL-1 in the side area DA_S may be substantially the same as each other.

Because each of a portion of the upper surface of the second encapsulating inorganic film IL2-1, which corresponds to the bending area DA_F, and a portion of the lower surface thereof, which corresponds to the bending area DA_F, in the unbent state (before bending) has a curved surface, a durability of the bending area DA_F may be enhanced as compared with the case, in which the upper surface and the lower surface of the second encapsulating inorganic film do not include curved surfaces, in the unbent state (before bending).

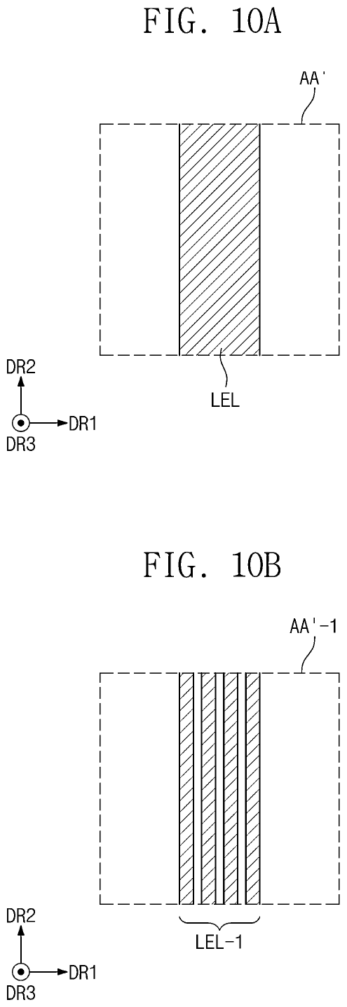

FIGS. 9A and 9B are schematic views illustrating contact angles depending on heights of surface energy according to an embodiment of the disclosure.

FIGS. 9A and 9B illustrate that the encapsulating organic film OL of the bending area DA_F is formed convexly in FIGS. 7A and 8. That is, it is illustrated to describe a difference between the contact angles depending on the surface energy.

Referring to FIG. 9A, when a liquid material WDR drops onto the low-energy layer LEL, the liquid material WDR may have a first contact angle θ1. In comparison, referring to FIG. 9B, when the liquid material WDR drops onto a high-energy layer HEL having surface energy that is higher than the surface energy of the low-energy layer LEL, the liquid material WDR may have a second contact angle θ2 that is smaller than the first contact angle θ1.

As described in FIG. 7A, surface energy of a portion corresponding to the low-energy layer LEL is lower than that of a surrounding portion of the first encapsulating inorganic film IL1. Accordingly, when the encapsulating organic film OL is formed on the first encapsulating inorganic film IL1, a surface area of the organic film OL becomes smaller in the bending area DA_F corresponding to the low-energy layer LEL, and the upper surface thereof may be formed to be convex.

Furthermore, as described above in FIG. 8, surface energy of a portion of the first encapsulating inorganic film IL1-1, which is not surface-treated, may be lower than that of a surrounding portion of the first encapsulating inorganic film IL1-1, which is surface treated. Accordingly, when the encapsulating organic film OL is formed on the first encapsulating inorganic film IL1, a surface area of the organic film OL-1 becomes smaller in the bending area DA_F having low surface energy, and the upper surface thereof may be formed to be convex.

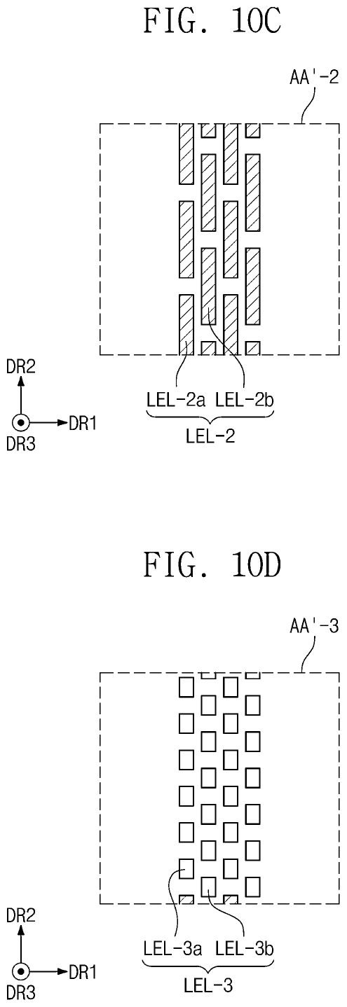

FIGS. 10A to 10D are enlarged plan views of the thin film encapsulating layer TFE (see FIG. 7A).

FIG. 10A is an enlarged plan view illustrating the low-energy layer LEL in the thin film encapsulating layer TFE (see FIG. 7A) corresponding to area AA′ of FIG. 4. FIG. 10A illustrates the embodiment of FIG. 7A on a plane. In an embodiment, as shown in FIG. 10A, the low-energy layer LEL is patterned in an integral shape to correspond to the bending area DA_F (see FIG. 4).

FIG. 10B is an enlarged plan view illustrating another embodiment of a low-energy layer LEL-1 in the thin film encapsulating layer TFE (see FIG. 7A) corresponding to area AA′ of FIG. 4. As compared with the low-energy layer LEL (see FIG. 10A) of FIG. 10A, the low-energy layer LEL-1 of FIG. 10B may have a shape, in which the bending area DA_F (see FIG. 4) is patterned in a plurality of shapes. In an embodiment, as illustrated in FIG. 10B, the patterns may be patterns that extend in the second direction DR2 and are spaced apart from each other along the first direction DR1.

FIG. 10C is an enlarged plan view illustrating another embodiment of a low-energy layer LEL-2 in the thin film encapsulating layer TFE (see FIG. 7A) corresponding to area AA′. As compared with the low-energy layer LEL (see FIG. 10A) of FIG. 10A, the low-energy layer LEL-2 of FIG. 10C may have a shape, in which the bending area DA_F (see FIG. 4) is patterned in a plurality of shapes. As compared with the low-energy layer LEL-1 of FIG. 10B, in the low-energy layer LEL-2 of FIG. 10C, a first pattern LEL-2a and a second pattern LEL-2b may be alternately disposed in the first direction DR1, and the first pattern LEL-2a and the second pattern LEL-2b may be patterns that are disposed to be askew in the second direction DR2.

FIG. 10D is an enlarged plan view illustrating another embodiment of a low-energy layer LEL-3 in the thin film encapsulating layer TFE (see FIG. 7A) corresponding to area AA′. As compared with the low-energy layer LEL (see FIG. 10A) of FIG. 10A, the low-energy layer LEL-3 of FIG. 10D may have a shape, in which the bending area DA_F (see FIG. 4) is patterned in a plurality of shapes. As compared with the low-energy layer LEL-1 of FIG. 10B, in the low-energy layer LEL-3 of FIG. 10D, a first pattern LEL-3a and a second pattern LEL-3b may be alternately disposed in the first direction DR1, and the first pattern LEL-3a and the second pattern LEL-3b may be patterns that are disposed to be askew in the second direction DR2. As compared with the low-energy layer LEL-2 of FIG. 10C, in the low-energy layer LEL-3 of FIG. 10D, lengths of the first pattern LEL-3a and the second pattern LEL-3b in the second direction DR2 are patterned to be short, and thus, an area of the bending area DA_F, which is occupied by the low-energy layer LEL-3, may be further decreased.

A pattern shape of the low-energy layer LEL is not limited to those shown in FIGS. 10A to 10D, and the low-energy layer LEL shown in FIGS. 10A to 10D are simply examples.

According to embodiments of the invention, as described herein, the display panel may enhance a durability of the bending area by making surface energy of portions of the thin film encapsulating layer to be different from each other.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel including a front area, and a bending area bent from one side of the front area in one direction to have a curvature, the display panel comprising:
a base layer;
a light emitting element layer disposed on the base layer, wherein the light emitting element layer includes a light emitting element; and
a thin film encapsulating layer disposed on the light emitting element layer,
wherein the thin film encapsulating layer includes:
a first encapsulating inorganic film disposed on the light emitting element layer;
an encapsulating organic film disposed on the first encapsulating inorganic film; and
a second encapsulating inorganic film disposed on the encapsulating organic film, wherein the second encapsulating inorganic film includes an upper surface spaced apart from the encapsulating organic film,
wherein the upper surface of the second encapsulating inorganic film has a curved surface corresponding to the bending area in a bent state, and a portion of the upper surface of the second encapsulating inorganic film corresponding to the bending area is convex in an opposite direction to the one direction in an unbent state.

2. The display panel of claim 1, wherein the second encapsulating inorganic film includes a lower surface contacting the encapsulating organic film, and
wherein the lower surface of the second encapsulating inorganic film has a curved surface corresponding to the bending area in the bent state, and a portion of the lower surface of the second encapsulating inorganic film corresponding to the bending area is concave in the opposite direction in the unbent state.

3. The display panel of claim 1, wherein the encapsulating organic film includes an upper surface contacting the second encapsulating inorganic film, and
wherein the upper surface of the encapsulating organic film has a curved surface corresponding to the bending area in the bent state, and a portion of the upper surface of the encapsulating organic film corresponding to the bending area is convex in the opposite direction in the unbent state.

4. The display panel of claim 1, wherein the thin film encapsulating layer further includes a low-energy layer disposed on the first encapsulating inorganic film in correspondence to the bending area and covered by the encapsulating organic film, and
wherein a surface energy of the low-energy layer is lower than a surface energy of the first encapsulating inorganic film.

5. The display panel of claim 4, wherein the low-energy layer includes an upper surface and a side surface, which contact the encapsulating organic film, and
wherein a whole portion of a front surface and a whole portion of the side surface of the low-energy layer are covered by the encapsulating organic film.

6. The display panel of claim 4, further comprising:
a side area extending from one side of the bending area and spaced apart from the front area.

7. The display panel of claim 1, further comprising:
a side area extending from one side of the bending area and spaced apart from the front area,
wherein the first encapsulating inorganic film includes a first part corresponding to the front area, a second part corresponding to the bending area, and a third part corresponding to the side area, and
wherein a surface energy of the first part and a surface energy of the third part of the first encapsulating inorganic film are higher than a surface energy of the second part of the first encapsulating inorganic film.

8. A display panel including a display area including a front area, and a bending area bent from one side of the front area in one direction to have a curvature, and a non-display area adjacent to the display area, the display panel comprising:
a base layer;
a light emitting element layer disposed on the base layer, wherein the light emitting element layer includes a light emitting element; and
a thin film encapsulating layer disposed on the light emitting element layer,
wherein the thin film encapsulating layer includes:
a first encapsulating inorganic film disposed on the light emitting element layer;
an encapsulating organic film disposed on the first encapsulating inorganic film;
a second encapsulating inorganic film disposed on the encapsulating organic film; and
a low-energy layer disposed on the first encapsulating inorganic film to correspond to the bending area, and covered by the encapsulating organic film, and
wherein a surface energy of the low-energy layer is lower than a surface energy of the first encapsulating inorganic film.

9. The display panel of claim 8, wherein the second encapsulating inorganic film includes an upper surface spaced apart from the encapsulating organic film, and a lower surface contacting the encapsulating organic film, and
wherein each of the upper surface and the lower surface of the second encapsulating inorganic film includes a curved surface in a bent state,
a portion of the upper surface of the second encapsulating inorganic film corresponding to the bending area is convex in an opposite direction to the one direction in an unbent state, and
a portion of the lower surface of the second encapsulating inorganic film corresponding to the bending area is concave in the opposite direction in the unbent state.

10. The display panel of claim 9, wherein the first encapsulating inorganic film includes an upper surface contacting the encapsulating organic film,
wherein the encapsulating organic film includes an upper surface contacting the second encapsulating inorganic film, and
wherein a length, in the bending area, from the upper surface of the first encapsulating inorganic film to a most convex portion of the upper surface of the encapsulating organic film in the one direction is 1.1 to 1.3 times of a length, in the front area, from the upper surface of the first encapsulating inorganic film to the upper surface of the encapsulating organic film in the one direction, in the unbent state.

11. The display panel of claim 9, wherein the display area further includes a side area extending from one side of the bending area and spaced apart from the front area,
wherein the first encapsulating inorganic film includes an upper surface contacting the encapsulating organic film,
wherein the encapsulating organic film includes an upper surface contacting the second encapsulating inorganic film, and
wherein, a length, in the bending area, from the upper surface of the first encapsulating inorganic film to a most convex portion of the upper surface of the encapsulating organic film in the one direction is 1.1 to 1.3 times of a length, in the side area, from the upper surface of the first encapsulating inorganic film to the upper surface of the encapsulating organic film in the one direction, in the unbent state.

12. The display panel of claim 8, wherein the encapsulating organic film includes an upper surface contacting the second encapsulating inorganic film, and
wherein the upper surface of the encapsulating organic film includes a curved surface in a bent state, and a portion of the upper surface of the encapsulating organic film corresponding to the bending area is convex in an opposite direction to the one direction in an unbent state.

13. The display panel of claim 8, wherein the low-energy layer includes an upper surface and a side surface contacting the encapsulating organic film, and
wherein a whole portion of the upper surface and a whole portion of the side surface of the low-energy layer are covered by the encapsulating organic film.

14. A display panel including a display area including a front area, a bending area bent from one side of the front area in one direction to have a curvature, and a side area extending from one side of the bending area and spaced apart from the front area, and a non-display area adjacent to the display area, the display panel comprising:
a base layer;
a light emitting element layer disposed on the base layer, wherein the light emitting element layer includes a light emitting element; and
a thin film encapsulating layer disposed on the light emitting element layer,
wherein the thin film encapsulating layer includes:
a first encapsulating inorganic film disposed on the light emitting element layer, wherein the first encapsulating inorganic film includes a first part corresponding the front area, a second part corresponding to the bending area, and a third part corresponding to the side area;
an encapsulating organic film disposed on the first encapsulating inorganic film; and
a second encapsulating inorganic film disposed on the encapsulating organic film, and
wherein, in the first encapsulating inorganic film, a surface energy of the first part and a surface energy of the third part are higher than a surface energy of the second part.

15. The display panel of claim 14, wherein the first part and the third part of the first encapsulating inorganic film are surface-treated with plasma.

16. The display panel of claim 14, wherein the second encapsulating inorganic film includes an upper surface spaced apart from the encapsulating organic film and a lower surface contacting the encapsulating organic film, and
wherein each of the upper surface and the lower surface of the second encapsulating inorganic film includes a curved surface corresponding to the bending area in a bent state,
a portion of the upper surface of the second encapsulating inorganic film is convex in an opposite direction to the one direction in an unbent state, and
a portion of the lower surface of the second encapsulating inorganic film is concave in the opposite direction in the unbent state.

17. The display panel of claim 16, wherein the first encapsulating inorganic film includes an upper surface contacting the encapsulating organic film, and
wherein, a length, in the bending area, from the upper surface of the first encapsulating inorganic film to a most convex portion of the lower surface of the second encapsulating inorganic film in the one direction is 1.1 to 1.3 times of a length, in the front area, from the upper surface of the first encapsulating inorganic film to the lower surface of the second encapsulating inorganic film in the one direction, in the unbent state.

18. The display panel of claim 16, wherein the first encapsulating inorganic film includes an upper surface contacting the encapsulating organic film, and
wherein, a length, in the bending area, from the upper surface of the first encapsulating inorganic film to a most convex portion of the lower surface of the second encapsulating inorganic film in the one direction is 1.1 to 1.3 times of a length, in the side area, from the upper surface of the first encapsulating inorganic film to the lower surface of the second encapsulating inorganic film in the one direction, in the unbent state.

19. The display panel of claim 14, wherein the encapsulating organic film includes an upper surface contacting the second encapsulating inorganic film, and
wherein the upper surface of the encapsulating organic film includes a curved surface in a bent state, and a portion of the upper surface of the encapsulating organic film corresponding to the bending area is convex in an opposite direction to the one direction in an unbent state.

20. The display panel of claim 14, wherein each of the first part, the second part, and the third part of the first encapsulating inorganic film contacts the encapsulating organic film.
